(19) United States
(12) Patent Application Publication
(10) Pub. No.: US 2020/0006233 A1
(43) Pub. Date: Jan. 2, 2020

(54) PIN ASSEMBLIES FOR PLATED VIAS

(71) Applicant: INTERNATIONAL BUSINESS MACHINES CORPORATION, Armonk, NY (US)

(72) Inventors: Kyle I. GIESEN, Beacon, NY (US); Matteo COCCHINI, Long Island City, NY (US); Kyle WONDERLY, Beacon, NY (US); Zachary T. DREISS, Beacon, NY (US); Juan MARTINEZ-MANTILLA, Poughkeepsie, NY (US)

(21) Appl. No.: 16/025,031

(22) Filed: Jul. 2, 2018

(51) Int. Cl. H01L 23/538; H01L 23/367; H05K 3/42; H05K 3/40; H05K 1/02

(52) U.S. Cl. CPC H01L 23/5384; H01L 23/3675; H05K 3/42; H05K 2201/10303; H05K 1/0203; H05K 2201/0305; H05K 3/4038

(57) ABSTRACT

A pin assembly is provided for a plated via of a circuit board. The pin assembly includes a pin sized for insertion into the plated via, and a plurality of expandable elements affixed to the pin. A conductive coating is disposed over the pin and over the plurality of expandable elements. With the pin assembly inserted into the plated via, one or more expandable elements of the plurality of expandable elements can be expanded within the plated via to enhance contact of the pin assembly to a wall of the plated via.

### BACKGROUND

Circuit boards, such as printed circuit boards, or wiring boards, are used in a wide variety of electronic products. A circuit board mechanically supports and electrically connects electronic components and/or electrical components using conductive lines, pads and other features on or within one or more layers of the circuit board. In circuit board design, a via may extend into or through the circuit board, and include, for instance, pads in appropriate positions on different layers on the board that are electrically connected by, for instance, a plating of the via within the board. For instance, a via may be made, in one or more embodiments, conductive by electroplating. There are a variety of types of circuit board vias, including, blind vias which are exposed on only one side of the board, through hole vias which extend through the board, thermal vias which carry heat away from power devices, etc.

Traditionally, should a via problem arise or be detected post manufacture of a circuit board, for instance, with a plated via in the board, reworking the board may be difficult, and the board may need to be discarded.

### SUMMARY

Certain shortcomings of the prior art are overcome and additional advantages are provided through the provision of a pin assembly for a plated via. The pin assembly includes a pin, a plurality of expandable elements, and a conductive coating. The pin is sized for insertion into the plated via, and the plurality of expandable elements are affixed to the pin. The conductive coating is disposed over the pin and the plurality of expandable elements. With the pin assembly inserted into the plated via, one or more expandable elements of the plurality of expandable elements can be expanded within the plated via to enhance contact of the pin assembly with the plated via.

In another aspect, a method of manufacturing a pin assembly for a plated via is provided. The method includes providing a pin sized for insertion into the plated via, and affixing a plurality of expandable elements to the pin. Further, the method includes applying a conductive coating over the pin and the plurality of expandable elements. The pin assembly is configured for insertion into the plated via, and once inserted, one or more expandable elements of the plurality of expandable elements can be expanded within the plated via to enhance physical contact of the pin assembly with the plated via.

In a further aspect, a method of using a pin assembly within a plated via of a circuit board is provided. The pin assembly includes a pin with a plurality of expandable elements affixed to the pin, and a conductive coating over the pin and the plurality of expandable elements. The method includes inserting the pin assembly into the plated via of the circuit board, and expanding within the plated via one or more elements of the plurality of expandable elements by applying a vacuum and heat to the pin assembly disposed within the plated via, where the one or more expandable elements expand to enhance contact of the pin assembly with the plated via.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A depicts a partial cross-sectional elevational view of one embodiment of a circuit board with a plated via, which can be enhanced, in accordance with one or more aspects of the present invention;

FIG. 1B depicts the circuit board via of FIG. 1A, with one embodiment of a pin structure shown disposed therein, illustrating insufficient pin to plated via contact;

FIG. 2A depicts a partial cross-sectional elevational view of one embodiment of a pin assembly disposed within a plated via of a circuit board, in accordance with one or more aspects of the present invention;

FIG. 2B depicts the assembly of FIG. 2A after expansion of one or more expandable elements of the pin assembly of FIG. 2A, illustrating enhanced pin assembly to plated via contact, in accordance with one or more aspects of the present invention;

FIGS. 3A-3D illustrate one embodiment of a process for forming a pin assembly for insertion into a plated via of a circuit board, in accordance with one or more aspects of the present invention;

FIGS. 4A-4C depict one embodiment of a process for forming expandable elements for attachment to a pin during fabrication of a pin assembly, in accordance with one or more aspects of the present invention;

FIG. 5A depicts one embodiment of a process for forming a pin assembly with a plurality of expandable elements affixed to a pin of the pin assembly, in accordance with one or more aspects of the present invention;

FIG. 5B depicts one embodiment of an intermediate assembly which may be useful in placing and affixing a plurality of expandable elements to a pin during fabrication of a pin assembly, in accordance with one or more aspects of the present invention;

FIG. 6A is a partial enlarged view of a pin assembly with a plurality of expandable elements affixed to a pin thereof, in accordance with one or more aspects of the present invention;

FIG. 6B depicts the assembly of FIG. 6A after expansion of the plurality of expandable elements, in accordance with one or more aspects of the present invention;

FIGS. 7A-7C depict alternate embodiments of a pin assembly configured for insertion into a plated via of a circuit board, in accordance with one or more aspects of the present invention;

FIG. 8A depicts a further embodiment of a pin assembly configured for insertion into a plated via, in accordance with one or more aspects of the present invention; and

FIG. 8B depicts the pin assembly of FIG. 8A after insertion into a plated via and after expansion of one or more expandable elements of the pin assembly, in accordance with one or more aspects of the present invention.

### DETAILED DESCRIPTION

Aspects of the present invention and certain features, advantages and details thereof, are explained more fully below with reference to the non-limiting example(s) illustrated in the accompanying drawings. Descriptions of well-known systems, devices, processing techniques, etc., are omitted so as to not unnecessarily obscure the invention in detail. It should be understood, however, that the detailed description and the specific example(s), while indicating aspects of the invention, are given by way of illustration only, and not by way of limitation. Various substitutions, modifications, additions, and/or other arrangements, within the spirit and/or scope of the underlying inventive concepts will be apparent to those skilled in the art from this disclosure. Note further that numerous inventive aspects and features are disclosed herein, and unless inconsistent, each disclosed aspect or feature is combinable with any other disclosed aspect or feature as desired for a particular application of an expandable pin assembly configured for insertion into a via of a circuit board, such as a plated via.

The illustrative embodiments may be described below using specific designs, architectures, protocols, layouts, schematics, or tools only as examples, and are not limited to the illustrative embodiments. Furthermore, the illustrative embodiments may be described in certain instances using particular tools, and processing environments only as example for clarity of description. The illustrative embodiments may be used in conjunction with other comparable or similarly purposed structures, systems, applications, or architectures.

The examples in this disclosure are used only for clarity of description and are not limiting to the illustrative embodiments. Additional operations, actions, tasks, activities, and manipulations will be conceivable from this disclosure and the same are contemplated within the scope of the illustrative embodiments.

Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed herein.

As noted, reworking a circuit board, such as a printed circuit board, wiring board, etc., is difficult post manufacture should a problem be detected or arise, such as with a plated via of the circuit board. For instance, re-spinning a circuit board is costly, and hand modifications to a circuit board are slow and can be challenging. In fact, certain board issues, such as a plated via defects, may be difficult to address without a new build of the circuit board. As related issues, current and heat dissipation in a circuit board are common issues to be addressed in dense circuit designs. The most congested areas have the most difficult constraints for heat dissipation, and a solution to address these constraints is often adding during design more vias, or increasing the size of the vias to conduct greater heat. Another circuit board issue is that, in operation, high current density could lead to electro-migration and degradation of plated via walls of the board.

A variety of approaches are available for filling a defective or underperforming via. These include, for instance, wave soldering, hand soldering, and conventional filled vias. Unfortunately, wave soldering requires a keep out zone of 250 mils around the via being filled, and other components. Hand soldering also requires a similar keep out zone and would be prone to failure modes, such as partial via fill. Conventional filled vias cannot always be done, particularly on high resolution vias, due to microstrip layer thickness constraints, and typically cannot be performed with components attached to the circuit board. Further, filled vias typically would not be undertaken for fixing an individual via, and can be a costly rework. The thicker the board, the higher the likelihood of quality control problems such as via plugging using a filled via approach.

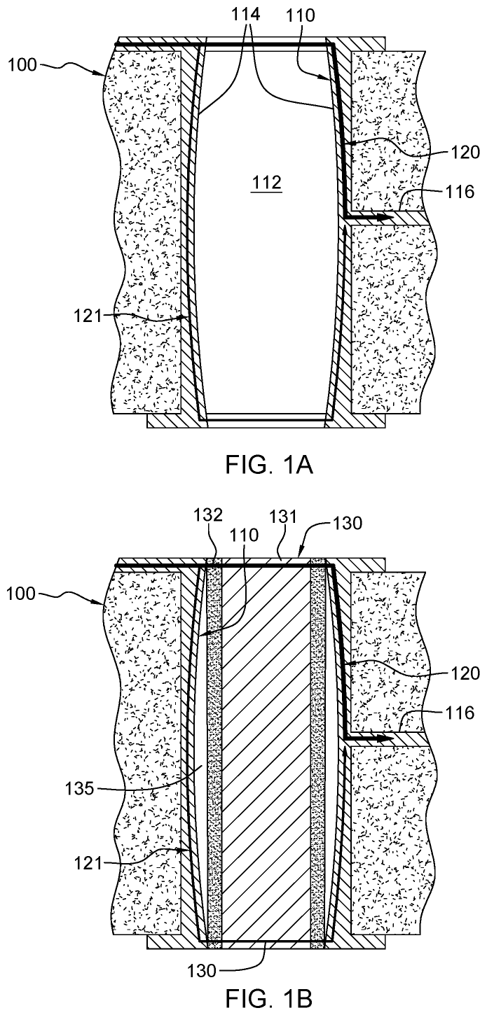

By way of example, FIG. 1A depicts one embodiment of a plated via 110 within a circuit board 100 which may benefit from reworking to enhance electrical and/or thermal characteristics of the plated via. As illustrated, plated via 110 may include a via 112, such as an opening, through hole, etc., formed within circuit board 100, which has been plated 114, such as by electroplating, with a conductive material, such as a metal. In one or more implementations, FIG. 1A depicts one example of a high resolution via, where the resolution of the via is defined by the board thickness divided by the via diameter. In high resolution vias today, a barreling effect may occur (as shown) where the electroplated via wall bows slightly outward in the middle. This bowing of the via wall may be intrinsic to the plating process. Also, as shown in FIG. 1A, circuit board 100 may have one or more power planes 116 centrally disposed within the circuit board and electrically connected to plated via 110. As illustrated, in this configuration the bulk of the current 120 passing through plated via 110 travels along the shortest path to power plane 116, with a smaller amount of current 121 passing along the opposite side of plated via 110, and then up to power plane 116. The result is that the via wall portion carrying the higher current 120 may be more likely to degrade, and result in a breakdown of the plated via.

As a possible solution, FIG. 1B depicts a pin structure 130 inserted into plated via 110, which includes a pin 131 with a conductive paste 132 over pin 131. Due to the bowing effect, however, pin structure 130 being sized for insertion into plated via 110 results in a gap 135 in the central region of the via between pin structure 130 and plated via 110. This means that pin structure 130 may only partially connect to the via wall at the top and bottom portions of plated via 110, as illustrated in FIG. 1B. Further, the extent of contact may be insufficient to modify the current flow paths 120, 121 through plated via 110, as shown. Thus, pin structure 130 would provide limited assistance in enhancing current transfer through plated via 110.

Addressing the above-noted issue, disclosed herein are expandable pin assemblies for plated vias of a circuit board. In an embodiment, the pin assembly includes a pin sized for insertion into the plated via, and a plurality of expandable elements affixed to the pin. A conductive coating is disposed over the pin and the plurality of expandable elements. With the pin inserted into the plated via, one or more expandable elements of the plurality of expandable elements can be expanded within the plated via to enhance contact of the pin assembly, and in particular, the conductive coating, to the plated via.

Note that, in one or more embodiments, the conductive coating may be a conductive paste that overlies, and is disposed between, expandable elements of the plurality of expandable elements. The conductive paste provides electrical and thermal coupling between the plated via and the pin of the pin assembly. In one or more embodiments, the conductive paste may be a solder paste. Further, the plurality of expandable elements may be affixed to, and cover at least a portion of the pin in an axial direction. In one or more embodiments, the plurality of expandable elements can be balloon-type structures formed of thermoplastic material and filled with an inert gas. For instance, the plurality of expandable elements may be formed of nylon, and filled with nitrogen.

In one or more implementations, the plurality of expandable elements include a first set of expandable elements and a second set of expandable elements, where expandable elements of the first set of expandable elements are larger in size than expandable elements of the second set of expandable elements. By way of example, expandable elements of the first set of expandable elements may be centrally affixed to the pin, and expandable elements of the second set of expandable elements may be affixed to the pin in an axial direction offset from the first set of expandable elements, such as on either side of the first set of expandable elements.

In one or more embodiments, the pin is a cylindrical pin with a recessed central pin portion of smaller diameter than a diameter of an end point of the cylindrical pin. The plurality of expandable elements can be affixed to the pin in the recessed central pin portion of smaller diameter. In one or more embodiments, a mechanical fin is disposed at one end of the pin sized to reside outside the plated via with the pin inserted into the plated via. The mechanical pin is configured to facilitate dissipating heat conducted by the pin assembly and can be formed integral with the pin, such as by a molding process.

In one or more embodiments, a method of using the pin assembly in a plated via of a circuit board is also provided. In an implementation, the method includes inserting the pin assembly into the plated via, and expanding within the plated via one or more expandable elements of the plurality of expandable elements by applying a vacuum and heat to the pin assembly disposed within the plated via. The one or more expandable elements expand to enhance contact of the pin assembly with the plated via, such as in a central portion of the plated via. In one or more embodiments, the plurality of expandable elements are balloon-type structures formed of thermoplastic material filled with an inert gas, and the expanding may include placing the pin assembly within the plated via into a vacuum chamber, and applying a vacuum and heat to the assembly to allow for deformation of the thermoplastic, and expansion of the one or more expandable elements to enhance contact of the pin assembly with the plated via. In one or more embodiments, inserting the pin assembly into the plated via includes inserting the pin assembly into the plated via until a shoulder stop of the pin assembly contacts a surface of a circuit board, such as an upper surface of the circuit board.

Advantageously, in operation the pin assembly can be a current and thermal strain reduction pin assembly, which is used to dissipate heat and decrease current density in a plated via. In an embodiment, the pin assembly is mounted during electronic component attach, or post circuit board build once a problem is discovered, or may be part of a planned enhancement to the circuit board assembly. By way of example, the pin assembly can advantageously be inserted into a plated via to pull heat up and away from the circuit board, then channel the heat into the airflow envelope intended for cooling of the circuit board. The pin assembly can also be used to reduce current density in a plated via, therefore mitigating reliability concerns due to electro-migration. Further, the pin assembly can be used to fix a defective plated via, for instance, a plated via that is cracked or otherwise broken. In operation, an expanding ring formed of one or more expandable elements of the pin assembly is used as discussed herein near the center of the plated via to ensure continuous contact between the pin assembly and the barrel-shaped plated via wall. The pin and heat sink of the pin assembly can be customized to fit any via size and maximize the contacting effect. The pins are coated with a conductive paste, such as solder paste, and when plugged into a plated via, or other via opening, can have shoulders or fins at one end to act as a mechanical stop to ensure proper positioning of the pin assembly within the plated via. In one or more embodiments, a heat sink is provided at one end which is tapered to allow for probing of the pin and to leave space for nearby components on the surface of the circuit board.

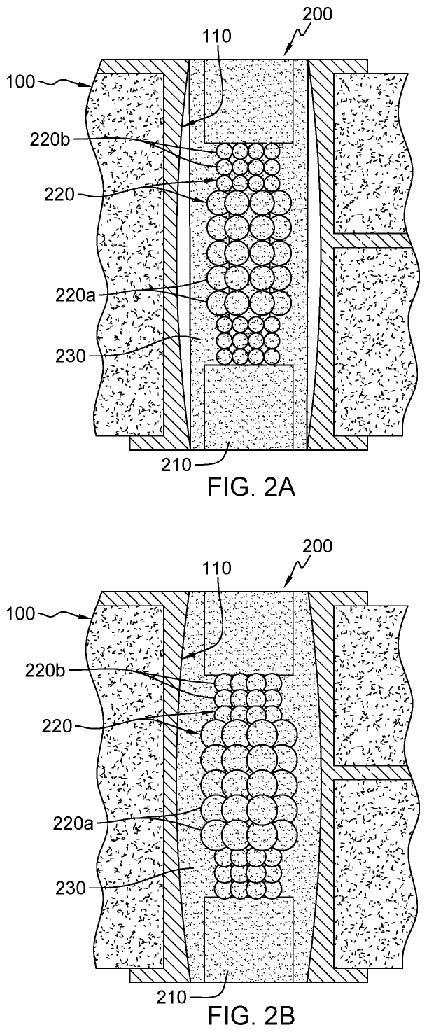

FIG. 2A depicts one embodiment of a pin assembly 200, in accordance with one or more aspects of the present invention, again shown inserted into plated via 110 of circuit board 100. In the illustrated embodiment, pin assembly 200 includes a pin 210, such as cylindrical, conductive pin, with a plurality of expandable elements 220 affixed to pin 210, and a conductive coating 230 over pin 210 and expandable elements 220. In one or more embodiments, the plurality of expandable elements 220 include, by way of example, a first set of expandable elements 220a and a second set of expandable elements 220b, with expandable elements 220a being larger in size than expandable elements 220b. Note that the sizing and positioning of expandable elements 220 can be configured for the particular plated via size and shape for which the pin assembly is designed. For instance, in the above-discussed high resolution plated vias, barrel shaping of the via is common, and thus, the first set of larger expandable elements 220a is centrally affixed to the pin, and the second set of expandable elements 220b is affixed laterally offset, for instance, on either side of expandable elements 220a. In one or more embodiments, conductive coating 230 is a conductive paste, such as a solder paste, which after expansion of the expandable elements contacts the plated via in a central portion of the plated via, as shown in FIG. 2B, notwithstanding the barrel shape of plated via 110. As a result, an improved, constant contact of conductive coating 230 to plated via 110 may be obtained. Also, note that the width of the expandable pin assembly is adaptable through the expansion of the expandable elements to provide good physical and electrical contact of the pin assembly to any plated via wall.

As explained herein, in one or more embodiments, the plurality of expandable elements are balloon-type structures made of a thermoplastic material, such as nylon, and filled with an inert gas, such as nitrogen. In the embodiment of FIGS. 2A & 2B, expandable elements 220 are shown as spheres, by way of example only. During a reflow process of the conductive paste, the inert gas within the expandable elements expands, permanently deforming the plastic material of the expandable elements. The pressure generated by the expanding expandable elements forces the conductive paste along the bow of the plated via wall, and forces the conductive paste to also flow between the expandable elements to ensure good contact with the pin itself, creating a continuous direct electrical (and thermal transfer) connection between the plated via wall and the pin along the length of the pin. Once expanded, the pin assembly thus compensates for the bowing in the high resolution via wall. Further, note that the shape and wall thicknesses of the expandable elements can be designed (that is, tailored or configured) to control the deformation shape attained in the resultant pin assembly, and thereby ensure that the conductive coating makes good electrical and thermal connection between the plated via wall and the pin of the pin assembly, which enhances electrical and thermal connection of the pin assembly to the plated via, thereby reducing the current load and thermal load otherwise to be conducted through the via wall plating.

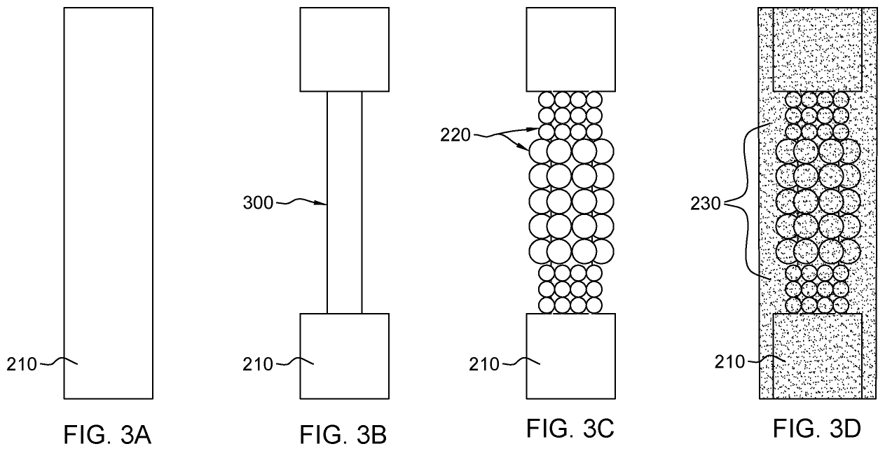

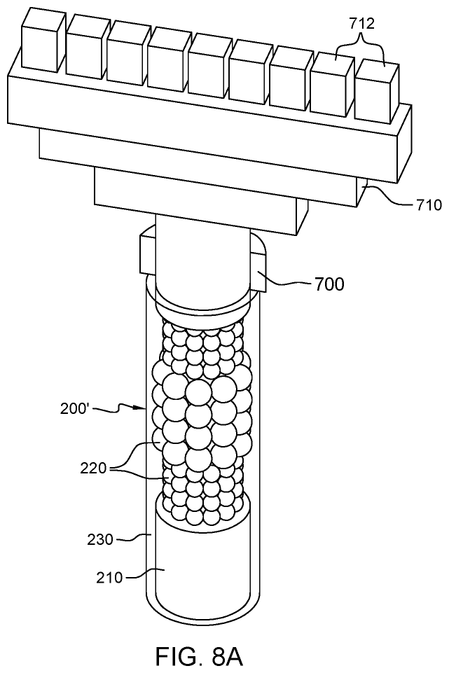

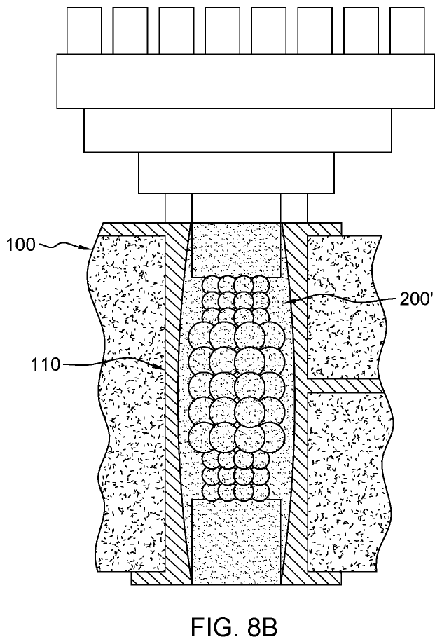

FIGS. 3A-5B depict one embodiment of a process for forming a pin assembly, such as pin assembly 200 of FIGS. 2A & 2B. As shown in FIG. 3A, a pin 210, such as a cylindrical pin is obtained. The pin has any desired configuration, and can include, for instance, shoulders or stops for positioning of the pin within a plated via of the circuit board, as well as a heat sink extending from one end of the pin, as in the embodiment described below with FIGS. 8A & 8B. Pin 210 is, for instance, a metal material, and depending on the configuration, can be a metal cast structure. The pin has a diameter approximating the thickness of the opening on both sides of the plated via to which the pin is to be inserted to, for instance, inhibit solder paste from flowing outward from the via during the processing described herein. As illustrated in FIG. 3B, a central region or core portion 300 of pin 210 is lathed to define a central pin region to receive the expandable elements. As a result, central region 300 has a smaller diameter than a diameter of the ends of pin 210, as illustrated in FIG. 3B. The region's smaller diameter allows for the attachment of expandable elements 220 to pin 210, as shown in FIG. 3C, while still allowing the assembly to be inserted into the plated via. As described above in connection with FIGS. 2A & 2B, expandable elements 220 are (in one or more embodiments) made of different sizes and configurations, depending upon the shape of the particular plated via in which the pin assembly is to be inserted, and for which the expandable elements are to be expanded to ensure good contact of the pin assembly to the plated via wall.

Expandable elements 220 can be similar in fabrication to balloons used today for angioplasty. For instance, spherical-shaped balloons with a diameter of 0.5 mm (19 mils) and a length of 0.5 mm (19 mils) are available today for angioplasty. The wall thickness of these balloons is typically 0.007 mm (0.25 mils), and the balloons may be formed using high temperature precision blow molding of nylon into a glass tube or beryllium copper mold. For instance, a typical injection blow mold temperature for nylon is 54-93° C., and the gas used in the process may be nitrogen. Capillary glass fibers are currently being produced with inner diameters of 6 μm. Copper etching can also be done today reliably to a resolution of 1 mil at a thickness of 0.5 mils using available photolithography techniques.

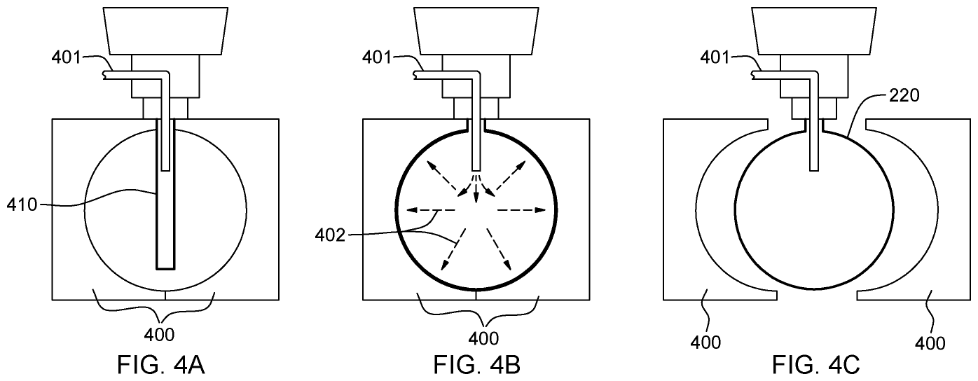

FIGS. 4A-4C depict one embodiment of a process for forming an expandable element 220 using a process similar to that described above. For instance, a mold 400, such as a copper mold is created using copper sheets and photolithography methods. In one or more embodiments, mold 400 may include two hemispheres which when placed together facilitate forming a sphere. Note that any desired expandable element shape may be configured using a similar process. By way of example, a two ounce copper sheet that is 2.4 mils thick can be etched to form a 1 mil diameter sphere or hemisphere using available circuit board fabrication methods. The mold 400 can be created, for instance, by etching two 1 mil diameter hemispheres with an opening for an injection nozzle 401, where a minimum current nozzle size today is 0.1 mil in diameter. The mold 400 and thermoplastic material 410 are assembled with nozzle 401 inserted into thermoplastic material 410. As noted, in one or more embodiments, the thermoplastic material can be nylon. The blow molding process is illustrated in FIG. 4B, which includes injecting (for instance) an inert gas 402 into the thermoplastic material 410 as part of a blow molding process to produce an expandable element with a wall thickness of, for instance, 0.25 mils (which is also the current thickness of an angioplasty balloon). Once expandable element 220 is formed, mold 400 may be separated from the expandable element, along with injection nozzle 401, with the nozzle opening in the expandable element being heat sealed, in one or more embodiments. The heat sealing process may use heat and pressure to seal the expandable element at the point where the nozzle was inserted during the molding process.

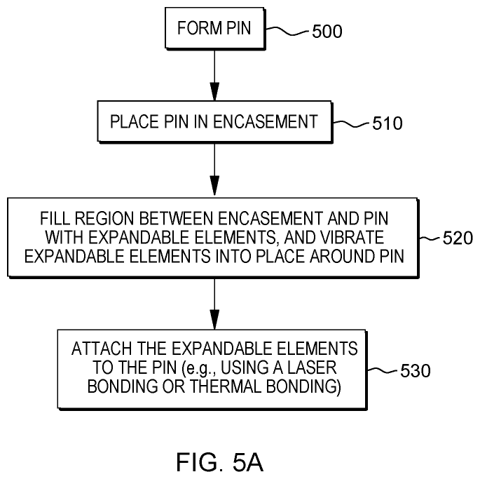

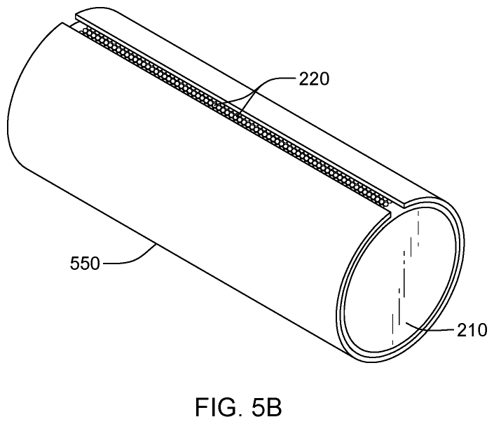

FIG. 5A depicts one embodiment of a process for attaching the expandable elements to the pin during forming of the pin assembly. A pin is formed, obtained, etc., and can be lathed, if desired, to provide a central recess region 500 (as shown in FIG. 3B). In one or more implementations, an encasement is provided which substantially encircles the pin 510, and has an opening for receiving the expandable elements 220, as shown in the embodiment of FIG. 5B. The space or gap between encasement 550 and pin 210 may be, in one or more implementations, substantially filled with expandable elements 220, and the assembly may be vibrated to move the expandable elements into place around the pin 520 (FIG. 5A). Once the expandable elements are positioned about the pin, the elements may be affixed to the pin 530. For instance, laser bonding may be used to attach the expandable elements to the pin. In such a method, the encasement 550 (FIG. 5B) can be made of clear glass-type material, and a laser beam can be focused so that the focal point is at the location where each expandable element contacts the pin, such as within the central pin portion in the embodiment of FIGS. 3A-3D. The expandable elements can be placed in stages using this method. The heat at the contact point(s) bonds the expandable elements to the pin. For instance, the contact point temperature should reach approximately 60° C. for bonding to occur in the case of nylon formed expandable elements. Another approach to attaching the expandable elements to the pin is to heat the pin once the expandable elements are in proper location about the pin. For instance, a heat source may be used to heat the pin which bonds the expandable elements to the pin at the point of contact. Again, the pin or contact between the pin and the expandable element is to reach approximately 60° C. for bonding to occur, that is, in the case of nylon formed expandable elements.

Returning to FIG. 3D, the resultant pin assembly 200 is formed by providing a conductive coating 230 over pin 210 and over expandable elements 220, as shown. As noted, in one or more implementations, the conductive coating 230 is a conductive paste, such as a solder paste. The conductive coating process can be done, in one or more implementations, at room temperature so that there is no initial deformation of the expandable elements, that is, before the pin assembly is inserted into the plated via. Also, the conductive coating of the pin and expandable elements can be performed in a vacuum chamber to ensure that the conductive material flows between the expandable elements into contact with the pin. As noted, the particular diameter(s) of the pin, resultant pin assembly, shapes and sizes of the expandable elements, as well as number of expandable elements, and position of expandable elements of the pin can all be varied as desired or required for a particular plated via configuration. For instance, pin assemblies 200 may be fabricated of different diameters and different lengths for different sized high-resolution plated vias. Further, note that the pin assemblies described herein can be used in combination with any plated via, such as any plate via having a non-uniform diameter along its length.

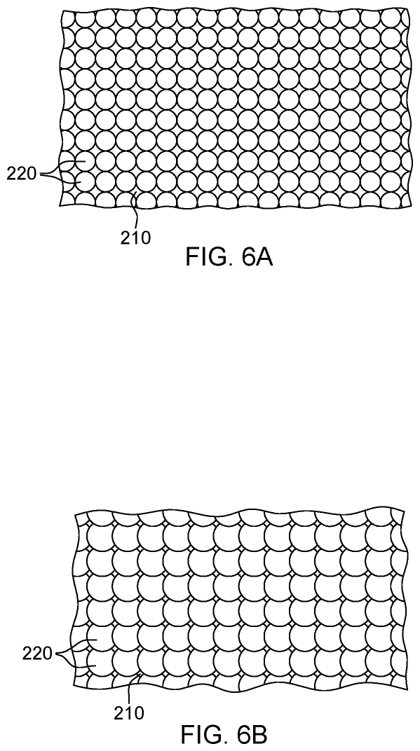

By way of example, FIG. 6A depicts a sample pattern of expandable elements 220 affixed to a pin 210 prior to expansion of the expandable elements, and FIG. 6B depicts the expandable elements 220 after expansion of the elements. As noted, in one or more implementations, the pin assembly is inserted into the plated via, and the resultant assembly is then placed into a vacuum chamber and subject to vacuum and heating in order to permanently deform the plastic material of the expandable elements. For instance, with the assembly placed within the vacuum chamber, heating of the pin and board assembly (in the presence of a vacuum) to, for instance, a temperature of about 105° C. can increase the volume of the expandable elements by 8×, which would correlate to an increase in radius of the expandable elements of 2×, as one example.

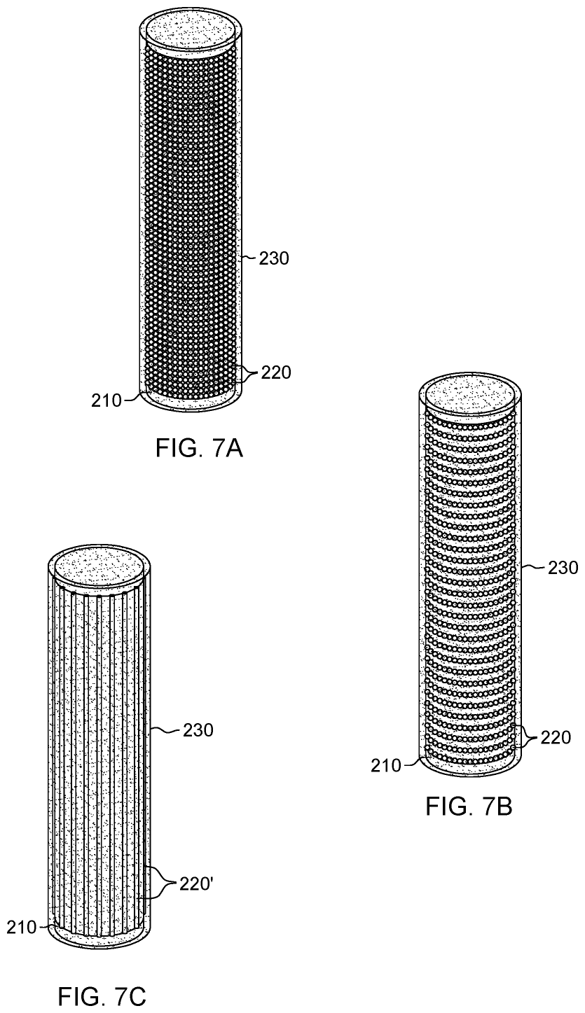

FIGS. 7A-7C depict alternate embodiments of a pin assembly configured for insertion into a plated via of a circuit board, in accordance with one or more aspects of the present invention. In FIG. 7A, the expandable elements 220 are shown substantially uniformly placed along the length of pin 210 in an axial direction. In FIG. 7B, a similar assembly is presented as in FIG. 7A, except the expandable elements are spaced apart in rings around pin 210. In FIG. 7C, a different configuration is shown wherein the expandable elements 220′ are elongate expandable elements that are affixed to pin 210 lengthwise, extending along the axial length of the pin. As noted, any desirable expandable element configuration and placement along the pin can be used depending on the particular plated via configuration with which the pin assembly is to be inserted and used.

FIGS. 8A & 8B depict an alternate embodiment of a pin assembly 200′, in accordance with one or more aspects of the present invention. In this configuration, pin assembly 200′ is substantially identical to pin assembly 200 described above in connection with FIGS. 2A-7C, however, one end of pin 210 is extended to project outward from the plated via for which the pin assembly is configured, with that end including, for instance, shoulders or mechanical fins 700, along with a heat sink structure 710, having heat dissipating fins 712. The heat sink may be employed to facilitate conducting heat away from the circuit board, and for dissipation into the airflow envelope provided for cooling the circuit board assembly. The pin assembly 200′ size and configuration can be customized, including the size and configuration of heat sink 710 to fit any via size, and to maximize the pin assembly's effect, as desired. Further, as shown, the pin assembly can include fins 700 (or shoulders or stops) to act as mechanical blocks facilitating placement of the pin assembly within the corresponding plated via. In particular, fins 700 are sized to contact a surface of the circuit board in a region around the plated via so as to function as a stop, thereby assisting in positioning the pin assembly within the plated via. Further, note that the heat sink 710 can have a variety of configurations. In one or more implementations, the tapered heat sink of FIGS. 8A & 8B can be desired for leaving space to allow electrical probing of the via with the pin assembly inserted, as well as to leave space for nearby components (not shown) around the plated via. In FIG. 8B, pin assembly 200′ is shown with the expandable elements expanded, and with the pin assembly making consistent contact with plated via 110.

Numerous advantages are provided by pin assemblies such as disclosed herein. For instance, the pin assemblies are mass producible and can be added during electronic component attach processing to be part of the solder process of the board, or could be added during bring-up testing of the board, for instance, in response to detecting an issue with one or more plated vias. In use, the pin assemblies disclosed herein increase the plated vias' thermal conductivity and electrical conductivity, and may be used to increase the dispersion of heat in electronically dense areas of the circuit board. Further, the pin assemblies disclosed may be mounted in and around areas of high heat, and increase a plated vias current carrying capability without modifying the board or card. Further, the pin assemblies disclosed herein are able to be used in an automated placement process, such as a pick and place process for electronic component attach.

More particularly, in one or more implementations, the pin assemblies disclosed herein can be used in association with plated vias where there are no other repair or enhancement processing options, including, being used to prevent electro-migration due to high current density, and provide a fix in the case of cracked or under-plated via walls. Further, the pin assemblies disclosed herein can be used to reduce the junction temperature of a chip where a heat sink cannot be attached, and additional can be used to reduce the junction temperature of a chip on an opposite side of the printed circuit board, where a heat sink is already attached. In a design process, the pin assemblies disclosed herein may be used to reduce the number of required plated vias without added cost of filing the vias. Further, the pin assemblies disclosed herein allow the via surface pad to be accessible for electronic probing, while the pin assembly is inserted into the plated via. The pin assembly disclosed can be used to create artificially filled vias in any location on the circuit board, without requiring the extra cost of actually filing the vias in situ using a plating process, or other approach.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A pin assembly for a plated via of a circuit board, the pin assembly comprising:
a pin sized for insertion into the plated via;
a plurality of expandable elements affixed to the pin; and
a conductive coating disposed over the pin and the plurality of expandable elements, wherein with the pin assembly inserted into the plated via, one or more expandable elements of the plurality of expandable elements can be expanded within the plated via to enhance contact of the pin assembly with the plated via.

2. The pin assembly of claim 1, wherein the conductive coating comprises a conductive paste that overlies, and is disposed between, expandable elements of the plurality of expandable elements.

3. The pin assembly of claim 2, wherein the conductive paste provides electrical connection between the plated via and the pin when the pin assembly is inserted into the plated via.

4. The pin assembly of claim 2, wherein the conductive paste is a solder paste.

5. The pin assembly of claim 1, wherein the plurality of expandable elements are affixed to, and cover, at least a portion of the pin in an axial or radial direction.

6. The pin assembly of claim 1, wherein the plurality of expandable elements are formed of a thermoplastic and filled with an inert gas.

7. The pin assembly of claim 1, wherein the plurality of expandable elements are formed of nylon, and filled with nitrogen.

8. The pin assembly of claim 1, wherein the plurality of expandable elements comprises a first set of expandable elements and a second set of expandable elements, expandable elements of the first set of expandable elements being larger in size than expandable elements of the second set of expandable elements.

9. The pin assembly of claim 7, wherein expandable elements of the first set of expandable elements are centrally affixed to the pin, and expandable elements of the second set of expandable elements are affixed to the pin in an axial direction offset from the first set of expandable elements.

10. The pin assembly of claim 1, wherein the pin is a cylindrical pin with a recessed central pin portion of smaller diameter than a diameter of an end portion of the cylindrical pin, the plurality of expandable elements being affixed to the pin in the recessed central pin portion of smaller diameter.

11. The pin assembly of claim 1, further comprising a mechanical fin at one end of the pin sized to reside outside the plated via with the pin inserted into the plated via, the mechanical fin facilitating dissipating heat conducted by the pin assembly.

12. A method of manufacturing a pin assembly for a plated via of a circuit board, the method comprising:
providing a pin sized for insertion into the plated via;
affixing a plurality of expandable elements to the pin; and
applying a conductive coating over the pin and the plurality of expandable elements, wherein the pin assembly is configured for insertion into the plated via and once inserted, one or more expandable elements of the plurality of expandable elements can be expanded within the plated via to enhance contact of the pin assembly with the plated via.

13. The method of claim 12, wherein the conductive coating comprises a conductive paste that overlies, and is disposed between, expandable elements of the plurality of expandable elements.

14. The method of claim 12, wherein the method further comprises forming the plurality of expandable elements as a plurality of thermoplastic elements filled with inert gas and the affixing comprises affixing the plurality of expandable elements to cover at least a portion of the pin in an axial direction.

15. The method of claim 14, wherein forming the plurality of expandable elements comprises forming a first set of expandable elements and a second set of expandable elements, where expandable elements of the first set of expandable elements are larger in size than expandable elements of the second set of expandable elements, and the affixing comprises centrally affixing to the pin expandable elements of the first set of expandable elements and affixing expandable elements of the second set of expandable elements to the pin in an axial direction offset from the first set of expandable elements.

16. The method of claim 12, wherein providing the pin comprises providing the pin with a recessed central pin portion of a smaller diameter than a diameter of an end portion of the pin, and the affixing comprises affixing the plurality of expandable elements to the pin in the recessed central pin portion of smaller diameter.

17. The method of claim 12, further comprising providing a mechanical fin at one end of the pin sized to reside outside the plated via with the pin inserted into the plated via, the mechanical fin facilitating dissipating heat conducted by the pin assembly.

18. The method of claim 12, wherein the method further comprises:
inserting the pin assembly into the plated via; and
expanding one or more expandable elements of the plurality of expandable elements by applying a vacuum and heat to the pin assembly disposed within the plated via, the one or more expandable elements expanding within the plated via to enhance contact of the pin assembly with the plated via.

19. The method of claim 18, wherein the plurality of expandable elements are formed of a thermoplastic filled with inert gas, and the expanding comprises placing the pin assembly within the plated via into a vacuum chamber, and applying the vacuum and the heat to allow for deformation of the thermoplastic, and expansion of the one or more expandable elements to enhance contact of the pin assembly with the plated via.

20. The method of claim 18, wherein the inserting comprises inserting the pin assembly into the plated via until a shoulder stop of the pin assembly contacts a surface of the circuit board.
